(19) United States
(12) Patent Application Publication
(10) Pub. No.: US 2024/0297195 A1
(43) Pub. Date: Sep. 5, 2024

(54) SOLID-STATE IMAGING DEVICE AND METHOD FOR MANUFACTURING SOLID-STATE IMAGING DEVICE

(71) Applicants: Kabushiki Kaisha Toshiba, Tokyo (JP); Toshiba Electronic Devices & Storage Corporation, Tokyo (JP)

(72) Inventor: Masao TAKAHASHI, Zama Kanagawa (JP)

(21) Appl. No.: 18/458,090

(22) Filed: Aug. 29, 2023

(30) Foreign Application Priority Data
Mar. 3, 2023 (JP) 2023-033079

(51) Int. Cl. H01L 27/146

(52) U.S. Cl. CPC H01L 27/14632; H01L 27/14623; H01L 27/14685; H01L 27/14689; H01L 27/14692

(57) ABSTRACT

A solid-state imaging device includes a semiconductor substrate that includes a first region in which a plurality of first photodiodes are arranged along a first direction, and a second region in which a plurality of second photodiodes are arranged along the first direction, and an insulating film that is disposed on the semiconductor substrate to cover the first region and the second region. The insulating film includes an optical path changing portion that changes an optical path of light incident on the insulating film on the first region and directed to the second region in at least an intermediate region between a first edge photodiode closest to the second region among the plurality of first photodiodes and a second edge photodiode closest to the first region among the plurality of second photodiodes.

### CROSS-REFERENCE TO RELATED APPLICATION(S)

This application is based upon and claims the benefit of priority from Japanese Patent Application No. 2023-033079, filed Mar. 3, 2023, the entire contents of which are incorporated herein by reference.

### FIELD

Embodiments described herein relate generally to a solid-state imaging device and a method for manufacturing a solid-state imaging device.

### BACKGROUND

Devices such as scanners use solid-state imaging devices such as linear image sensors in which pixels are arrayed in a predetermined direction. In the solid-state imaging device, an insulating film such as an antireflection film is disposed on a photodiode constituting the pixel. Due to the influence of this insulating film, ripples may occur in a spectrum of the photodiode. In order to reduce such ripples, a structure in which a recess is formed in the insulating film on the photodiode is known.

The solid-state imaging device is manufactured by forming a plurality of solid-state imaging devices (e.g., chips) on a semiconductor wafer (hereinafter, simply referred to as a “wafer”) and then segmenting the chips into individual pieces by dicing. In contrast, the wafer on which the plurality of solid-state imaging devices are formed may be shipped as it is without being segmented. In such a case, during quality inspection or the like before shipment, light incident on one chip may propagate to and be received by an adjacent chip by changing an optical path due to the recess of the insulating film on the photodiode. As a result, there is a possibility that photosensitivity of a specific pixel of the adjacent chip is overestimated, and quality inspection cannot be correctly performed.

### DESCRIPTION OF THE DRAWINGS

FIG. 1A is a partial top view of a solid-state imaging device according to a first embodiment.

FIG. 1B is a cross-sectional view taken along line I-I of FIG. 1A.

FIG. 1C is an enlarged view of an inter-chip region of FIG. 1B showing an effect of the solid-state imaging device according to the first embodiment.

FIG. 1D is a diagram showing layout conditions of an optical path changing portion.

FIGS. 2A1 to 2A4 are cross-sectional views showing an example of processes of a method for manufacturing a solid-state imaging device according to the first embodiment.

FIGS. 2B1 to 2B4 are cross-sectional views showing an example of processes of the method for manufacturing the solid-state imaging device according to the first embodiment subsequently to FIGS. 2A1 to 2A4.

FIGS. 2C1 to 2C3 are cross-sectional views showing an example of processes of the method for manufacturing the solid-state imaging device according to the first embodiment subsequently to FIGS. 2B1 to 2B4.

FIG. 3 is a partial top view of a solid-state imaging device according to Modification Example 1 of the first embodiment.

FIG. 4 is a partial top view of a solid-state imaging device according to Modification Example 2 of the first embodiment.

FIG. 5 is a partial top view of a solid-state imaging device according to Modification Example 3 of the first embodiment.

FIG. 6 is a top view of a solid-state imaging device according to Modification Example 4 of the first embodiment.

FIG. 7A is a partial top view of a solid-state imaging device according to a second embodiment.

FIG. 7B is a cross-sectional view taken along line I-I of FIG. 7A.

FIG. 7C is an enlarged view of an inter-chip region of FIG. 7B showing an effect of the solid-state imaging device according to the second embodiment.

FIG. 8 is a partial cross-sectional view of a solid-state imaging device according to a third embodiment.

### DETAILED DESCRIPTION

Embodiments provide a solid-state imaging device that can be inspected more reliably and a method for manufacturing such a solid-state imaging device.

In general, according to one embodiment, a solid-state imaging device includes a semiconductor substrate that includes a first region in which a plurality of first photodiodes are arranged along a first direction, and a second region in which a plurality of second photodiodes are arranged along the first direction, and an insulating film that is disposed on the semiconductor substrate to cover the first region and the second region. The insulating film includes an optical path changing portion that changes an optical path of light incident on the insulating film on the first region and directed to the second region in at least an intermediate region between a first edge photodiode closest to the second region among the plurality of first photodiodes and a second edge photodiode closest to the first region among the plurality of second photodiodes.

Hereinafter, embodiments of the present disclosure will be described with reference to the drawings. The embodiments do not limit the scope of the present disclosure. The drawings are schematic or conceptual, and a ratio of sizes between parts or the like may not be identical to an actual ratio. In the specification and the drawings, elements similar to the elements described above with respect to the above-mentioned drawings are designated by the identical reference numerals, and detailed description thereof will be omitted as appropriate.

For the sake of convenience in description, an XYZ orthogonal coordinate system is adopted as shown in the drawings. A Z-axis direction is a stacking direction (thickness direction) of a solid-state imaging device. In a Z direction, an insulating film 4 side is also referred to as “upper”, and a semiconductor substrate 2 side is also referred to as “lower”. These expressions are for the sake of convenience and are irrelevant to a direction of gravity.

### First Embodiment

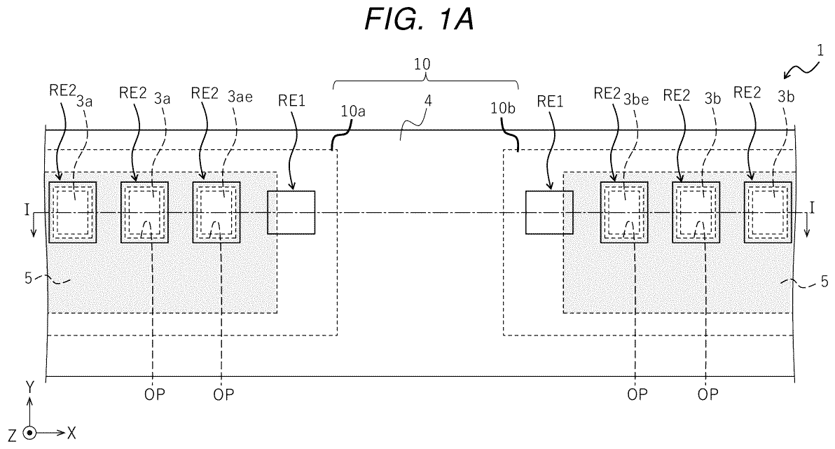

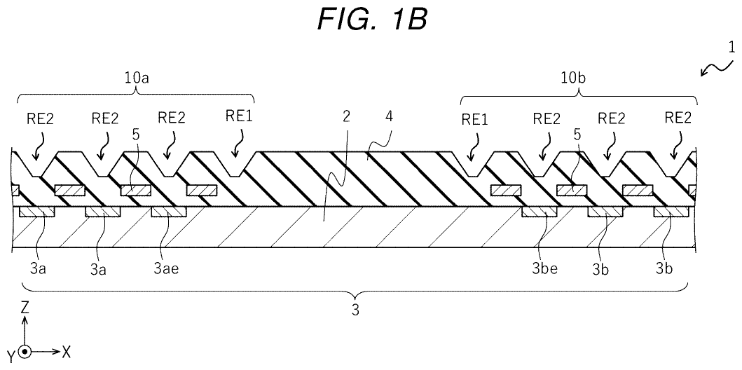

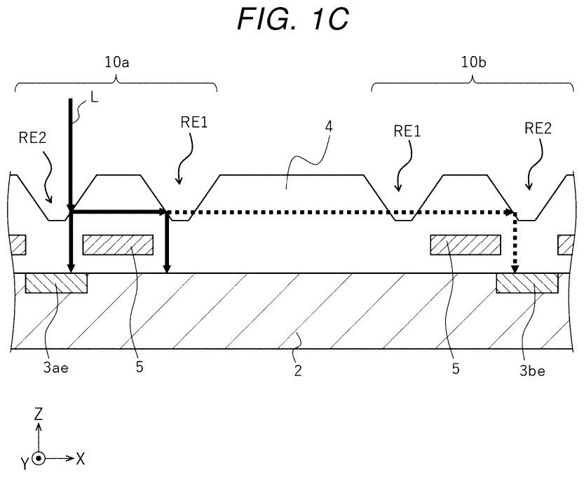

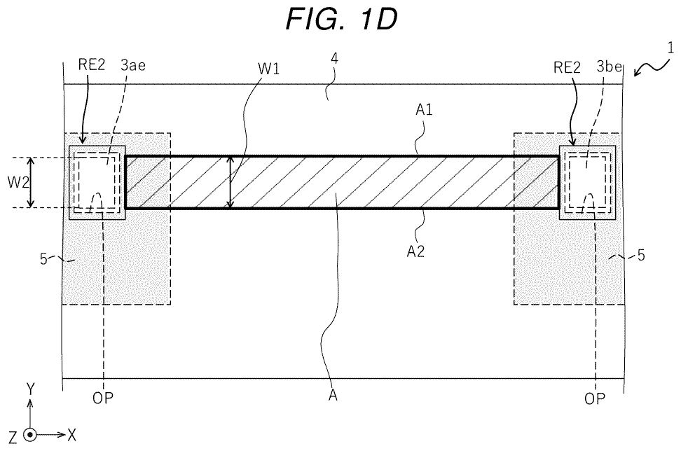

A solid-state imaging device 1 according to a first embodiment will be described with reference to FIGS. 1A and 1B. FIG. 1A is a partial top view of the solid-state imaging device 1. FIG. 1B is a cross-sectional view taken along line I-I shown in FIG. 1A.

The solid-state imaging device 1 includes a plurality of chips 10a and 10b. In the following description, the chip 10a and the chip 10b are collectively referred to as the chip 10 when there is no need to distinguish these chips from each other. The chip 10 is, for example, a linear image sensor. The chip 10 may be a CMOS sensor or may be a CCD sensor. In the present application, the solid-state imaging device 1 includes the plurality of chips 10, and is, for example, a wafer including a plurality of non-segmented chips. A user may freely segment the solid-state imaging device 1 into one or a plurality of chips 10.

The chip 10a and the chip 10b are shown in FIG. 1A as an example. Another chip (not shown) may be disposed on both sides of the chip 10a in a Y-axis direction and on an opposite side of the chip 10b in an X-axis direction. Similarly, other chips (not shown) may be disposed on both sides of the chip 10b in the Y-axis direction and on an opposite side of the chip 10a in the X-axis direction.

As shown in FIGS. 1A and 1B, the solid-state imaging device 1 includes a semiconductor substrate 2, a plurality of photodiodes 3a and 3b, photodiodes 3ae and 3be, an insulating film 4, and light shielding metals 5. Hereinafter, details of each element will be described with reference to FIGS. 1A to 1D. In the following description, the photodiodes 3a, 3b, 3ae, and 3be are collectively referred to as the photodiodes 3 when there is no need to distinguish these photodiodes from each other.

The semiconductor substrate 2 is, for example, a substrate made of a semiconductor such as silicon (Si) or silicon carbide (SiC). The semiconductor substrate 2 is, for example, a wafer formed by slicing an ingot. The semiconductor substrate 2 may be an epitaxial layer, may be at least part of the semiconductor substrate, or may include the epitaxial layer and the semiconductor substrate.

The photodiodes 3a, 3b, 3ae, and 3be are arranged on a straight line along an array direction (X-axis direction) on the semiconductor substrate 2. The photodiodes 3a, 3b, 3ae, and 3be receive light incident substantially perpendicularly (in the Z-axis direction) on the solid-state imaging device 1 (or the chip 10).

A plurality of photodiodes 3a are arranged in the region 10a. A plurality of photodiodes 3b are arranged in the region 10b. In this manner, the semiconductor substrate 2 has the region 10a in which the plurality of photodiodes 3a are arranged along the X-axis direction and the region 10b in which the plurality of photodiodes 3b are arranged along the X-axis direction.

The photodiode 3ae is the photodiode closest to the region 10b among the photodiodes arranged in the region 10a. The photodiode 3be is the photodiode closest to the region 10a among the photodiodes arranged in the region 10b. The photodiodes 3ae and 3be are examples of “edge photodiodes”. An array of the photodiodes 3a and an array of the photodiodes 3b need not be arranged along the same straight line (for example, may be shifted in the Y-axis direction).

When the chip 10 is a linear image sensor or the like, objects for blocking light, such as circuits and/or wirings for the linear image sensor, may not be in a region between the photodiode 3ae and the photodiode 3be (that is, an edge portion of the chip). The reason is that, in the linear image sensor or the like, since a plurality of segmented chips are disposed on a sensor module substrate to form one pixel row, the chips are disposed up to the edge portion of the chip.

The insulating film 4 is disposed on the semiconductor substrate 2 to cover the region 10a and 10b. The insulating film 4 may include an antireflection film. The insulating film 4 is made of, for example, silicon oxide, aluminum oxide, or the like. Recesses RE1 and recesses RE2 are provided in the insulating film 4.

The recesses RE1 are provided in the region (region A to be described later) between the photodiode 3ae and the photodiode 3be. Although two recesses RE1 are shown between the photodiode 3ae and the photodiode 3be in FIG. 1A, only one recess RE1 may be provided between the photodiodes 3ae and 3be. The recess RE1 is an example of an optical path changing portion.

The recess RE1 is formed as an optical path changing portion that changes an optical path of light incident on the insulating film 4 on the region 10a and directed to the region 10b. A depth of the recess RE1 is substantially the same as a depth of the recess RE2, as shown in FIG. 1B. The depth of the recess RE1 is preferably greater than or equal to the depth of the recess RE2.

Although the recess RE1 is provided outside the region 10 in FIG. 1A, part or all of the recesses RE1 may be provided inside the region 10.

The recess RE2 is provided in a location corresponding to each photodiode 3 (right above the photodiode 3 in the present embodiment) in order to reduce variations in photosensitivity of the photodiode 3 with respect to changes in a wavelength of incident light).

When the solid-state imaging device 1 is used as a color sensor, a color filter may be disposed on the insulating film 4, inside the insulating film 4, or between the insulating film 4 and the semiconductor substrate 2. The color filter includes, for example, a red color filter that transmits red light and attenuates the rest of light, a green color filter that transmits green light and attenuates the rest of light, and a blue color filter that transmits blue light and attenuates the rest of light. The insulating film 4 may be configured to function as a color filter.

The light shielding metals 5 are disposed in the insulating film 4. Specifically, the light shielding metals 5 are disposed in the regions 10a and 10b. The light shielding metal 5 in the region 10a has openings OP in locations corresponding to the photodiodes 3a and 3ae, and shields light other than light incident on the photodiodes 3a and 3ae from the Z-axis direction. The light shielding metal 5 in the region 10b has openings OP in locations corresponding to the photodiodes 3b and 3be, and shields light other than light incident on the photodiodes 3b and 3be from the Z-axis direction. The light shielding metal 5 is made of metal such as copper or aluminum.

### Effects

Here, the effects of the present embodiment will be described with reference to FIG. 1C. FIG. 1C is an enlarged view of a region between the region 10a and the region 10b of FIG. 1B. When light L is incident on the region 10a, part of the light L is refracted by the recess RE2 and propagates in the X-axis direction.

At this time, when the recess RE1 is not provided in the insulating film 4, in some shapes of the recess RE2, there is a possibility that the light L propagates to the region 10b and is incident on the photodiode 3b (here, the photodiode 3be) as indicated by a dotted line. That is, there is a possibility that light leaks from the region 10a to the region 10b. In this case, more light is incident on the photodiode 3be, and photosensitivity of the photodiode 3be is overestimated. As a result, during quality control, for example, the photodiode 3be cannot be properly evaluated, and thus, the chip 10b cannot be properly evaluated.

In contrast, in the present embodiment, the recess RE1 is provided, and thus, an optical path of the light L that is refracted by the recess RE2 of the region 10a and propagates in the X-axis direction is changed by the recess RE1 as indicated by a solid arrow and does not propagate to the region 10b. In this manner, the recess RE1 is provided, and thus, light can be prevented from leaking from the region 10a to the region 10b. Consequently, the photodiode 3be and the chip 10b can be properly evaluated, for example, during quality control. That is, the quality evaluation for each chip 10 can be properly performed. The depth of the recess RE1 is greater than or equal to the depth of the recess RE2, and thus, light can be more effectively prevented from leaking from the region 10a to the region 10b.

### Layout of Optical Path Changing Portion

Here, layout conditions of the optical path changing portion will be described with reference to FIG. 1D. FIG. 1D is a diagram showing the layout conditions of the optical path changing portion. Part or all of the optical path changing portion may cross the region (intermediate region) A between the photodiode 3ae and the photodiode 3be in the Y-axis direction. As shown in FIG. 1D, the region A is a region that includes a side A1 and a side A2, connects the photodiode 3ae and the photodiode 3be at a shortest distance, and does not overlap with the recess RE2 in regions where a width W1 in the Y-axis direction is equal to a width W2 of the photodiodes 3 in the Y-axis direction. As shown in FIG. 1D, the sides A1 and A2 are sides connecting an edge of the photodiode 3ae in the Y-axis direction and an edge of the photodiode 3be in the Y-axis direction.

That is, the optical path changing portion may include at least part of the side A1 and at least part of the side A2 parallel to the region A in the X-axis direction and may extend from the side A1 to the side A2. A crossing (extending) direction of the optical path changing portion is not limited to being parallel to the Y-axis direction.

The optical path changing portion satisfies the above layout conditions, and thus, for example, the light L that is refracted by the recess RE2 and propagates in the X-axis direction can be prevented from propagating from the region 10a to the region 10b (or from the region 10b to the region 10a) (the light can be prevented from leaking to the adjacent chip).

### Method for Manufacturing Solid-State Imaging Device

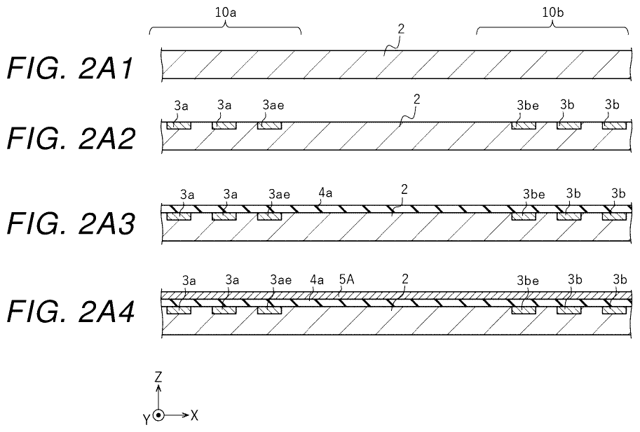

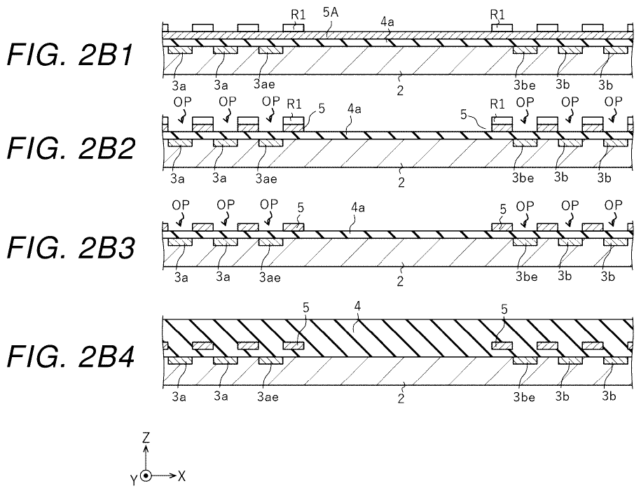

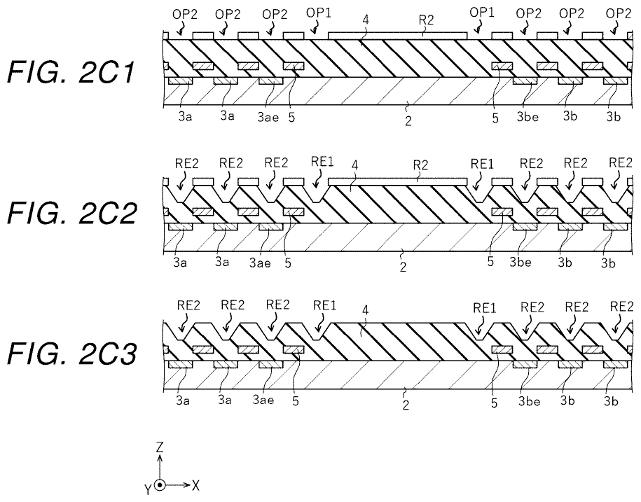

Next, an example of a method for manufacturing the solid-state imaging device 1 will be described with reference to FIGS. 2A1 to 2C3. FIGS. 2A1 to 2C3 are process cross-sectional views showing the method for manufacturing the solid-state imaging device 1.

First, as shown in FIG. 2A1, the semiconductor substrate 2 is prepared. Subsequently, as shown in FIG. 2A2, the photodiodes 3 are formed on an upper surface of the semiconductor substrate 2 along the X-axis direction. Specifically, the photodiodes 3a are formed in the region 10a along the X-axis direction, and the photodiodes 3b are formed in the region 10b along the X-axis direction.

Subsequently, as shown in FIG. 2A3, an insulating film 4a to be part of the insulating film 4 is formed on the semiconductor substrate 2 to cover the region 10a and the region 10b. The insulating film 4a is formed, for example, by depositing an insulating material on the photodiodes 3 by physical vapor deposition (PVD), chemical vapor deposition (CVD), or the like. The insulating material is, for example, silicon oxide, aluminum oxide, or the like.

Subsequently, as shown in FIG. 2A4, a metal layer 5A is formed by depositing metal on the insulating film 4a by, for example, a vapor deposition method or a sputtering method. The metal layer 5A is made of, for example, copper, aluminum, or the like.

Subsequently, as shown in FIG. 2B1, a resist mask R1 is formed on the metal layer 5A by applying a photoresist on the metal layer 5A and selectively exposing and developing the photoresist.

Subsequently, as shown in FIG. 2B2, a portion of the metal layer 5A that is not covered with the resist mask R1 is removed by etching. Consequently, the light shielding metal 5 having the openings OP is formed in each region. The openings OP are formed in locations corresponding to the photodiodes 3. The etching in this process is, for example, wet etching or dry etching using an etchant. As shown in FIG. 2B3, the resist mask R1 is removed by using, for example, a developer.

Subsequently, as shown in FIG. 2B4, the insulating film 4 having the light shielding metal 5 disposed therein is formed by depositing an insulating material again to bury the light shielding metal 5 therein.

Subsequently, as shown in FIG. 2C1, a resist mask R2 is formed by applying a photoresist on the insulating film 4 and selectively exposing and developing the photoresist. In the resist mask R2, openings OP1 are provided in the region A between the photodiode 3ae and the photodiode 3be, and openings OP2 are provided in locations corresponding to the photodiodes 3a, 3ae, 3b, and 3be. The openings OP1 cross the region A in the Y-axis direction.

Subsequently, as shown in FIG. 2C2, the portion of the insulating film 4 that is not covered with the resist mask R2 is removed by etching, for example, by wet etching using an etchant. Consequently, the recesses RE1 and the recesses RE2 are formed. Finally, as shown in FIG. 2C3, the resist mask R2 is removed by using, for example, a developer.

Through the above processes, the solid-state imaging device 1 according to the embodiment is manufactured. The above description is merely an example of the method for manufacturing the solid-state imaging device 1, and the solid-state imaging device 1 can be manufactured by other methods as well.

In the above processes, since the recesses RE1 and the recesses RE2 are simultaneously formed, there is no need to separately perform the process of providing the recesses RE1. Accordingly, the solid-state imaging device 1 can be manufactured at low cost and with high manufacturing efficiency. The recesses RE1 and the recesses RE2 may be formed by separate processes.

As described above, in the solid-state imaging device 1 according to the present embodiment, the recesses RE1 are provided in the insulating film 4 between the photodiode 3ae and the photodiode 3be. Consequently, for example, the light incident on the region 10a can be prevented from leaking to the adjacent region 10b. The photosensitivity of a specific photodiode 3 in the region 10b can be prevented from being overestimated. The same applies to the light incident on the region 10b. Accordingly, according to the present embodiment, the quality inspection of each chip 10 can be properly performed, and the quality inspection of the entire solid-state imaging device 1 can be properly performed.

The optical path changing portion (recess RE1) may be provided in any shape as long as the optical path changing portion satisfies the layout conditions described above. Hereinafter, Modification Examples 1 to 4 of the present embodiment will be described. Effects equivalent to or greater than the effects of the above-described embodiment can be obtained in any of the modification examples. In addition, since the shape (layout) of the recess RE1 when the solid-state imaging device 1 is viewed from above is a main change in Modification Examples 1 to 4, only a partial top view is shown, and a cross-sectional view is omitted.

### Modification Example 1

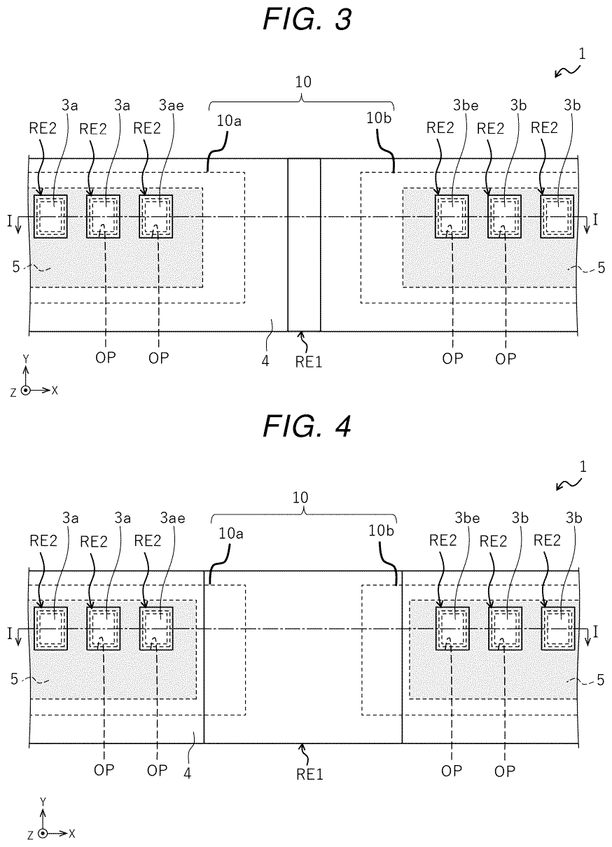

A solid-state imaging device 1 according to Modification Example 1 of the first embodiment will be described with reference to FIG. 3.

FIG. 3 is a partial top view of Modification Example 1 of the solid-state imaging device according to the first embodiment. As shown in FIG. 3, in the solid-state imaging device 1, the recess RE1 extends along the Y-axis direction. For example, the recess RE1 extends along the Y-axis direction to include the regions from upper edges to lower edges of the regions 10a and 10b. In this manner, the recess RE1 is widely formed in the Y-axis direction, and thus, light can be more effectively prevented from leaking from the region 10a to the region 10b. In the present modification example, although the recess RE1 as the optical path changing portion is orthogonal to the region A, the present disclosure is not limited thereto, and the recess RE1 may obliquely cross the region A.

### Modification Example 2

Next, a solid-state imaging device 1 according to Modification Example 2 of the first embodiment will be described with reference to FIG. 4. FIG. 4 is a partial top view of Modification Example 2 of the solid-state imaging device according to the first embodiment. As shown in FIG. 4, in the present modification example, the recess RE1 extends widely along the Y-axis direction and also extends widely along the X-axis direction. The recess RE1 extends widely in the X-axis direction and the Y-axis direction in a region between the recess RE2 provided above the photodiode 3ae and the recess RE2 provided above the photodiode 3be. Consequently, light can be more effectively prevented from leaking from the region 10a to the region 10b.

### Modification Example 3

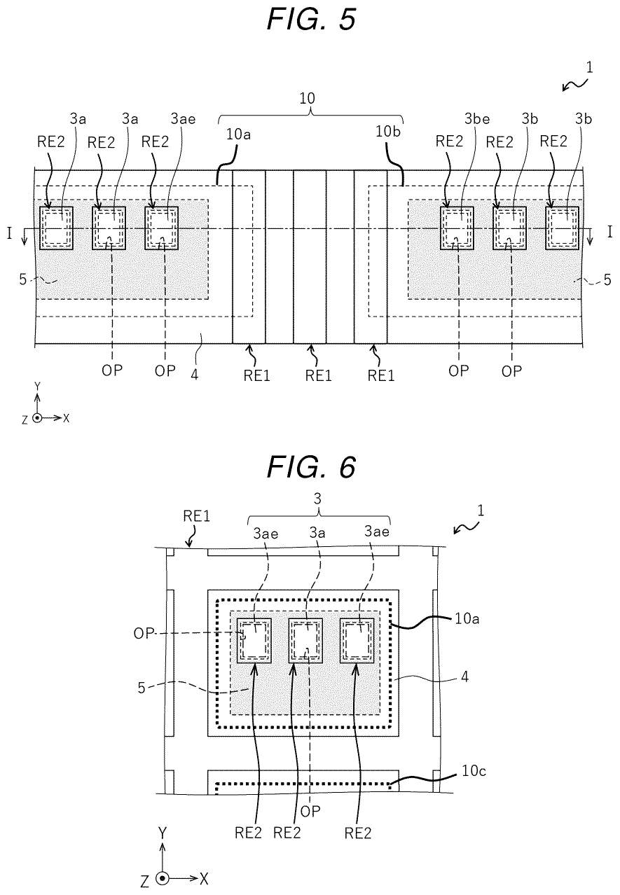

Next, a solid-state imaging device 1 according to Modification Example 3 of the first embodiment will be described with reference to FIG. 5. FIG. 5 is a partial top view of Modification Example 3 of the solid-state imaging device according to the first embodiment. As shown in FIG. 5, in the present modification example, a plurality of (three in FIG. 5) recesses RE1 extending in the Y-axis direction described in Modification Example 1 are provided in the X-axis direction. Consequently, light can be more effectively prevented from leaking from the region 10a to the region 10b.

### Modification Example 4

Next, a solid-state imaging device 1 according to Modification Example 4 of the first embodiment will be described with reference to FIG. 6. FIG. 6 is a partial top view of Modification Example 4 of the solid-state imaging device according to the first embodiment. As shown in FIG. 6, in the present modification example, the recess RE1 surrounds the region 10a. The recess RE1 may be provided in the insulating film 4 located above the light shielding metal 5, and may surround at least the plurality of photodiodes 3a and 3ae arranged in the region 10a. Consequently, light can be more effectively prevented from leaking from the region 10a to the region 10b, and light can be prevented from leaking from the region 10a to a region adjacent in the Y-axis direction (for example, a region 10c in FIG. 6).

Although three photodiodes 3 are arranged in the region 10a in FIG. 6, the number of photodiodes 3 is not limited thereto. A recess may also surround the photodiode in another region 10 adjacent to the region 10a.

The recess RE1 having the shape (layout) as described in Modification Examples 1 to 4 may correspond to a dicing line for dicing performed when the solid-state imaging device 1 is segmented into a plurality of chips 10. Consequently, the recess RE1 can be used as a mark (guide) for dicing.

### Second Embodiment

Next, a solid-state imaging device 1A according to a second embodiment will be described. In the first embodiment, the depth of the recess RE1 was substantially the same as the depth of the recess RE2. In contrast, in the second embodiment, the depth of the recess RE1 reaches the semiconductor substrate 2, and the semiconductor substrate 2 is exposed at a bottom surface of the recess RE1. Consequently, light can be more reliably prevented from leaking from the region 10a to the region 10b. Hereinafter, the second embodiment will be described focusing on differences from the first embodiment.

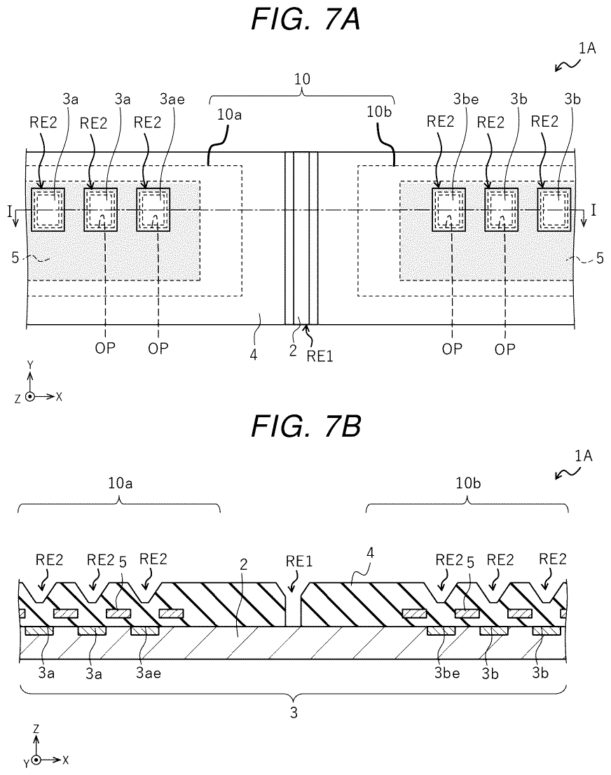

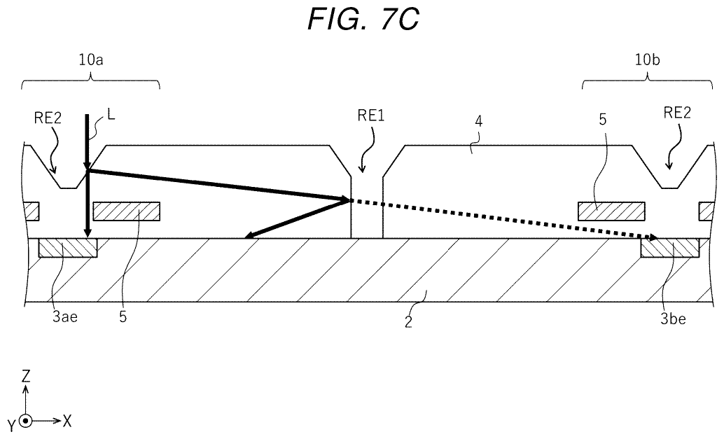

FIG. 7A is a partial top view showing the solid-state imaging device 1A according to the second embodiment. FIG. 7B is a cross-sectional view taken along line I-I of FIG. 7A. Elements with the same names or functions as the names or functions in the drawings described in the first embodiment are given the same reference numerals. Hereinafter, descriptions will be omitted except for items that are changed or added.

In the present embodiment, the recess RE1 reaches the semiconductor substrate 2 as shown in FIG. 7B. That is, the semiconductor substrate 2 is exposed on the bottom surface of the recess RE1.

Here, the effect of the recess RE1 reaching the semiconductor substrate 2 will be described with reference to FIG. 7C. FIG. 7C is an enlarged view of the region between the region 10a and the region 10b of FIG. 7B. When the light L is incident on the region 10a, part of the light L is refracted by the recess RE2 and propagates in the X-axis direction.

At this time, in some shapes of the recess RE2, the light L propagates downward. In this case, when the recess formed in the region A is not deep enough, there is a possibility that the light L propagates to the region 10b through the bottom of the recess and is incident on the photodiode 3b (here, the photodiode 3be). That is, there is a possibility that light leaks from the region 10a to the region 10b.

In contrast, in the second embodiment, the depth of the recess RE1 reaches the semiconductor substrate 2. Consequently, the light L that is not incident on the region 10a is blocked by the recess RE1 and does not propagate to the region 10b, as indicated by a solid-line arrow even though which route the light propagates in the X-axis direction. In this manner, since the depth of the recess RE1 reaches the semiconductor substrate 2, light can be more effectively prevented from leaking from the region 10a to the region 10b. Moreover, the photosensitivity of only a specific photodiode 3 in the adjacent region can be prevented from being overestimated. The same applies to the light incident on the region 10b. As a result, the quality inspection of each chip 10 can be properly performed, and the quality inspection of the entire solid-state imaging device 1A can be properly performed.

### Third Embodiment

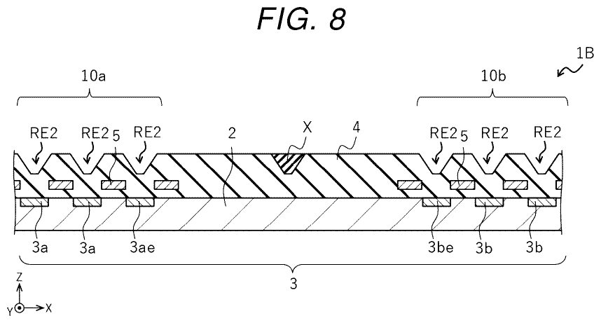

Next, a solid-state imaging device 1B according to a third embodiment will be described with reference to FIG. 8. Although the optical path changing portion is formed by the recess in the first and second embodiments, in the third embodiment, the optical path changing portion is buried in the insulating film 4, and is made of a material X having a refractive index different from a refractive index of the insulating film 4. The material X may be, for example, silicon nitride, or may be a material such as a metal having a light shielding property. Consequently, light can be more reliably prevented from leaking from the region 10a to the region 10b.

The material X may be buried in the insulating film 4. That is, the material X may not be exposed on a surface of the insulating film 4.

In the solid-state imaging device 1B according to the present embodiment, the optical path changing portion is made of the material X having the refractive index different from the refractive index of the insulating film 4. Consequently, for example, the light incident on the region 10a can be prevented from leaking to the adjacent region 10b. The photosensitivity of only a specific photodiode 3 in the region 10b can be prevented from being overestimated. The same applies to the light incident on the region 10b. Accordingly, according to the present embodiment, the quality inspection of each chip 10 can be properly performed, and the quality inspection of the entire solid-state imaging device 1B can be properly performed.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A solid-state imaging device, comprising:
a semiconductor substrate that includes a first region in which a plurality of first photodiodes are arranged along a first direction, and a second region in which a plurality of second photodiodes are arranged along the first direction; and
an insulating film that is disposed on the semiconductor substrate to cover the first region and the second region,
wherein the insulating film includes an optical path changing portion that changes an optical path of light incident on the insulating film on the first region and directed to the second region in at least an intermediate region between a first edge photodiode closest to the second region among the plurality of first photodiodes and a second edge photodiode closest to the first region among the plurality of second photodiodes.

2. The solid-state imaging device according to claim 1, wherein the optical path changing portion is a first recess provided in the insulating film in the intermediate region.

3. The solid-state imaging device according to claim 2, wherein the first recess corresponds to a dicing line for dicing performed when the solid-state imaging device is segmented into a plurality of chips.

4. The solid-state imaging device according to claim 2, wherein
the insulating film includes a plurality of second recesses in locations corresponding to the plurality of first photodiodes and the plurality of second photodiodes, and
a depth of the first recess is greater than or equal to a depth of the second recess.

5. The solid-state imaging device according to claim 4, wherein the semiconductor substrate is exposed on a bottom surface of the first recess.

6. The solid-state imaging device according to claim 1, wherein the optical path changing portion is buried in the insulating film, and is made of a material having a refractive index different from a refractive index of the insulating film.

7. The solid-state imaging device according to claim 1, wherein the optical path changing portion crosses the intermediate region in a second direction substantially orthogonal to the first direction.

8. The solid-state imaging device according to claim 7, wherein the optical path changing portion extends along the second direction orthogonal to the first direction to edges of the solid-state imaging device in the second direction.

9. The solid-state imaging device according to claim 1, wherein the optical path changing portion surrounds the plurality of first photodiodes.

10. The solid-state imaging device according to claim 1, wherein
the solid-state imaging device is a linear image sensor, and
a circuit and/or a wiring for the linear image sensor is not disposed between the first edge photodiode and the second edge photodiode.

11. A method for manufacturing a solid-state imaging device, comprising:
preparing a semiconductor substrate that includes a first region in which a plurality of first photodiodes are arranged along a first direction, and a second region in which a plurality of second photodiodes are arranged along the first direction;
forming an insulating film on the semiconductor substrate to cover the first region and the second region; and
forming, in the insulating film, an optical path changing portion that changes an optical path of light incident on the insulating film on the first region and directed to the second region in at least an intermediate region between a first edge photodiode closest to the second region among the plurality of first photodiodes and a second edge photodiode closest to the first region among the plurality of second photodiodes.

12. The method for manufacturing a solid-state imaging device according to claim 11,
wherein the forming of the optical path changing portion includes
forming, on the insulating film, a resist in which a first opening is provided in the intermediate region and second openings are provided in locations corresponding to the plurality of first photodiodes and the plurality of second photodiodes, and
forming a first recess in a location corresponding to the first opening and forming second recesses in locations corresponding to the second openings by etching the insulating film with the resist as a mask, and
wherein the optical path changing portion comprises the first recess.

13. The method for manufacturing a solid-state imaging device according to claim 12, wherein a depth of the first recess is greater than or equal to the depth of the second recesses.

14. The method for manufacturing a solid-state imaging device according to claim 12, further comprising:
forming a light shielding metal layer having openings corresponding to locations of the first and second photodiodes, wherein light shielding metal layer is covered by the insulating layer and the second recesses are aligned with the openings in a direction perpendicular to a surface of the semiconductor substrate.

15. The method for manufacturing a solid-state imaging device according to claim 11, further comprising:
dicing along the first recess to separate the first region from the second region.

16. A solid-state imaging device, comprising:
a semiconductor substrate that includes a first region in which a plurality of first photodiodes are arranged along a first direction, and a second region in which a plurality of second photodiodes are arranged along the first direction; and
an insulating film that is disposed on the semiconductor substrate to cover the first region and the second region,
wherein an upper surface of the insulating film includes a first recess at a location that is between the first and second regions and second recesses at locations directly above the first and second photodiodes in a thickness direction of the semiconductor substrate, the first recess extending in a second direction that crosses the first direction and orthogonal to the thickness direction of the semiconductor substrate and having a depth that is greater than or equal to a depth of the second recesses.

17. The solid-state imaging device according to claim 16, wherein the first recess extends in the second direction to both ends of the insulating film in the second direction.

18. The solid-state imaging device according to claim 16, wherein the semiconductor substrate is exposed on a bottom surface of the first recess.

19. The solid-state imaging device according to claim 16, wherein the first recess is one of a plurality of recesses that extend in the second direction to both ends of the insulating film in the second direction.

20. The solid-state imaging device according to claim 16, wherein the first recess is a part of a rectangular recess that surrounds the plurality of first photodiodes.
